(19) United States
(12) Patent Application Publication
(10) Pub. No.: US 2024/0413021 A1
(43) Pub. Date: Dec. 12, 2024

(54) METHOD OF MEASURING THICKNESS OF SEMICONDUCTOR WAFER AND INSPECTING BONDING VOIDS

(71) Applicant: Micron Technology, Inc., Boise, ID (US)

(72) Inventors: Wei Zhou, Boise, ID (US); Kunal R. Parekh, Boise, ID (US)

(21) Appl. No.: 18/668,106

(22) Filed: May 17, 2024

Related U.S. Application Data
(60) Provisional application No. 63/472,432, filed on Jun. 12, 2023.

(51) Int. Cl. H01L 21/66; H01L 21/67; H01L 21/78; H01L 25/18

(52) U.S. Cl. CPC H01L 22/12; H01L 21/67092; H01L 21/78; H01L 22/14; H01L 25/18

(57) ABSTRACT

Methods, apparatuses, and systems related to a semiconductor apparatus having one or more dielectric structures used to detect bonding voids during manufacturing. In some embodiments, a semiconductor wafer includes the dielectric structures. After the wafer is bonded to another structure, capacitances may be measured across the dielectric structures and the other wafer. The measured capacitance can be used to detect or characterize any bonding voids that may have been introduced during the wafer bonding process.

### CROSS-REFERENCE TO RELATED APPLICATION(S)

The present application claims priority to U.S. Provisional Patent Application No. 63/472,432, filed Jun. 12, 2023, the disclosure of which is incorporated herein by reference in its entirety.

### TECHNICAL FIELD

The present technology is directed to apparatuses, such as to semiconductor devices including memory and processors, and several embodiments are directed to semiconductor devices having structures used for void inspection during manufacturing.

### BACKGROUND

The current trend in semiconductor fabrication is to manufacture smaller and faster devices with a higher density of components for computers, cell phones, pagers, personal digital assistants, and many other products. To facilitate the current trend, circuits may be attached or stacked on top of each other, such as through wafer bonding.

Wafer bonding is a packaging technology on wafer-level for the fabrication of microelectromechanical systems (MEMS), nanoelectromechanical systems (NEMS), microelectronics and optoelectronics, ensuring a mechanically stable and hermetically sealed encapsulation. The bonded wafers are characterized in order to evaluate a technology's yield, bonding strength and level of hermeticity either for fabricated devices or for the purpose of process development. Conventionally, such characterization may utilize optical methods to detect or characterize the amount of cracks or interfacial voids.

Wafer bonding may also be leveraged to reduce the thickness of a target semiconductor device (e.g., die), such as during wafer-level thinning processes. The structural integrity of a target wafer may be enhanced or protected by wafer bonding the target wafer to a carrier wafer. The enhanced structural integrity can allow the target wafer to be thinned (via, e.g., backside/inactive side removal) to a lesser thickness than otherwise possible, such as 10 μm or less.

The reduced target thickness also reduces the distance between active and inactive sides of the processed wafer. As such, accurate assessment and tracking of the wafer thickness is required to avoid excessive thinning that damages the circuit components (e.g., implanted/doped regions) that extend toward the inactive side. Since warpage, interfacial voids, and other bonding imperfections can contribute to the excessive thinning, accurately characterizing the bonded combination of the target and carrier wafers becomes crucial in thinning the target wafer to ultra-thin levels (e.g., 10 μm or less).

### BRIEF DESCRIPTION OF THE DRAWINGS

FIG. 1 is a schematic cross-sectional view of two bonded wafers prior to a wafer thinning process in accordance with embodiments of the technology.

FIG. 2 is a schematic cross-sectional view of two bonded wafers after the wafer thinning process in accordance with embodiments of the technology.

FIG. 3 is a schematic cross-sectional view of two bonded wafers prior to the wafer thinning process in accordance with embodiments of the technology.

FIG. 4 is a schematic cross-sectional view of two bonded wafers after the wafer thinning process in accordance with embodiments of the technology.

FIG. 5 is a schematic cross-sectional view of two bonded wafers after the wafer thinning process in accordance with embodiments of the technology.

FIG. 6 is a schematic cross-sectional view of a resulting semiconductor die after singulation in accordance with embodiments of the technology.

FIG. 7 is a schematic view of wafer bonded dies in accordance with embodiments of the technology.

FIG. 8 is a block diagram of an apparatus in accordance with an embodiment of the technology.

FIG. 9 is a flow diagram illustrating an example method of manufacturing an apparatus in accordance with an embodiment of the technology.

FIG. 10 is a schematic view of a system that includes an apparatus in accordance with an embodiment of the present technology.

### DETAILED DESCRIPTION

The disclosed technologies provide improvements in measuring a thickness of a semiconductor wafer and inspecting bonding voids between bonded wafers. The improved detection/characterization of the bonding voids can improve accuracies in measuring the thickness of one or more of the bonded dies during a thinning process. Wafer thinning can provide multiple advantages to the resulting semiconductor chip, such as improved heat dissipation efficiency, reduction in the size of the chip with increase in the proportion of effective functional volume, reduction of internal stress of the chip, and improved electrical performance of the chip. In utilizing wafer thinning to provide ultra-thin profiles (e.g., 10 μm thickness or less), the manufacturing process may bond the processed semiconductor wafer to a carrier wafer to enhance the structural integrity. Moreover, to reach the ultra-thin profile without damaging the circuits on the thinned wafer, detecting and characterizing bonding voids in bonded wafer pairs may be required to ensure robust bonding processes and to increase yield.

Currently available tools for wafer thickness measurement require a long amount of operation time to obtain thickness measurements. Additionally, bonding void inspection is typically performed using infrared (IR) transmission imaging, Scanning Acoustic Microscopy (CSAM), and the like. IR transmission imaging is a non-contact technique that has limited spatial resolution and thus limited ability to detect thin bonding voids. CSAM provides a higher spatial resolution but requires using coupling fluid to perform inspection. Such conventional measurements require the manufacturing process to stop and for the processed device to be moved to a separate environment dedicated for the measurement. As such, the measurements introduce further delays and potential damages to transition between the manufacturing process and the measurement process.

The disclosed technologies address such problems by including dielectric structures on a front side of a target semiconductor wafer prior to a bonding process that bonds the target wafer to a carrier wafer. In some embodiments, multiple cavities with depths equal to or greater than thickness control structures are formed on the target wafer and then filled with dielectric material to build multiple dielectric structures. Once a wafer thinning process begins, the back side of the semiconductor wafer is thinned until the dielectric structures are exposed. Capacitances at each of the dielectric structures can be measured and analyzed to determine thickness of the remaining semiconductor wafer. In determining the thickness, the capacitances can represent the existence of bonding voids between the semiconductor wafer and the carrier wafer or a measure that corresponds to a size and/or a quantity of such voids.

The capacitances may be measured using a conductive bond chuck and one or more probe pads. The conductive bond chuck can directly contact the carrier wafer (e.g., on a surface opposite the bonded surface), and the one or more probe pads can directly contact the exposed surfaces of the dielectric structures. Accordingly, the conductive bond chuck and the probe pads can effectively function as capacitor terminals, and the dielectric structures and the carrier wafer can function as the dielectric separating the capacitor terminals. The resulting capacitive structure can have an expected or a predetermined capacitance. When the bonded structure includes the bonding voids between the carrier wafer and the target wafer (e.g., at or about the dielectric structures), the measured capacitance can deviate from the expected capacitance. Thus, the measured capacitance can be used to detect the bonding voids and/or characterize the severity of the bonding voids, which can be further processed to characterize the thickness of the target wafer.

The dielectric structures allow in situ inspection of bonding voids without the need for transition to dedicated measuring environments, such as coupling fluids used in one or more conventional methods. Additionally, the capacitance measurements allow for a simple and quick thickness measurement of the remaining semiconductor wafer.

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

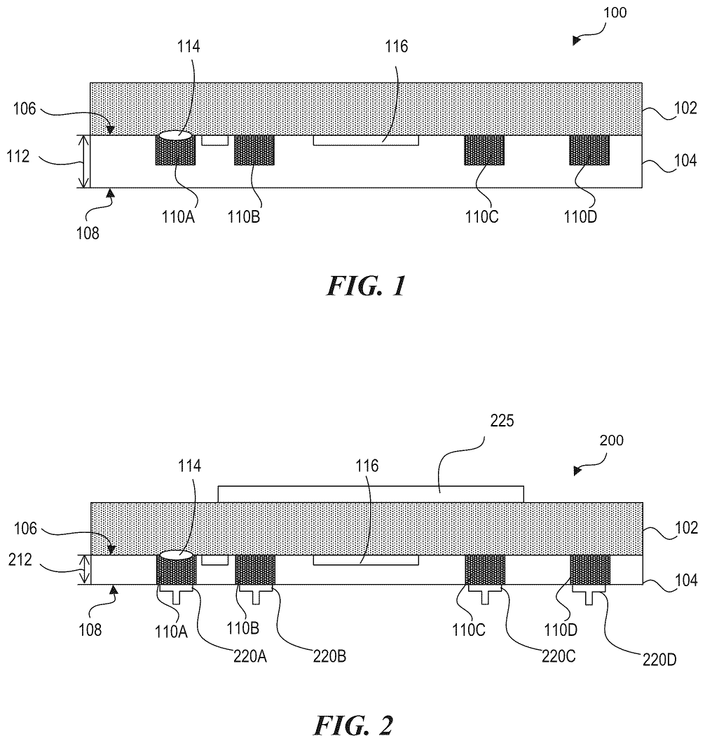

FIG. 1 is a schematic cross-sectional view of two bonded wafers 100 prior to a wafer thinning process in accordance with embodiments of the technology. The bonded wafers 100 can include a carrier wafer 102 and a target semiconductor wafer 104.

The target semiconductor wafer 104 can have an active front portion 106 and an inactive back portion 108. Active circuits 116 can be formed on the active front portion 106 of the target semiconductor wafer 104. In some embodiments, multiple cavities are formed on the active front portion 106 of the target semiconductor wafer 104 then filled with dielectric material to build multiple dielectric structures 110A-D. The vertically extending dielectric structures 110A-D can provide an electrical function for the active circuits 116. For example, the dielectric structures 110A-D can encase, surround, abut, or separate circuit components, such as doped regions. In some embodiments, the dielectric structures 110 can include a 2W structure/region having oxide material, such as SiO₂, ZrO₂, HfO₂, SiON, and/or the like therein.

Depths of the dielectric structures 110A-D depend on the depths of the cavities formed on the active front portion 106. In some embodiments, the depths of the dielectric structures are equal to an initial thickness 112 of the target semiconductor wafer 104 such that the dielectric structures are exposed on the inactive back portion 108 prior to the wafer thinning process. In other embodiments, the depths of the dielectric structures are less than the initial thickness 112 of the target semiconductor wafer 104 such that the dielectric structures are unexposed. The cavity depth and the corresponding height/depth of the dielectric structures 110A-D can correspond to a targeted thickness for the target semiconductor wafer 104.

Prior to the wafer thinning process, the target semiconductor wafer 104 can be bonded with the carrier wafer 102 for safe handling and processing, such as for providing enhanced structural support for the target semiconductor wafer 104. During the bonding process, bonding voids 114 can be inadvertently formed between the carrier wafer 102 and the active front portion 106 of the target semiconductor wafer 104. In some embodiments, the bonding voids 114 are trapped gas caused by uneven bonding surfaces. In other embodiments, the bonding voids 114 result from particles that are deposited on the bonding surfaces. The resulting bonding voids can vary in size, quantity, and location. For example, as shown in FIG. 1, a single bonding void 114 is formed adjacent to the dielectric structure 110A. In another example, bonding voids 114 are formed adjacent to the active circuits 116, the dielectric structures 110B and 110C, and other locations without any structure where the carrier wafer 102 is bonded with the target semiconductor wafer 104. In another example, no bonding voids are formed anywhere between the carrier wafer 102 and the target semiconductor wafer 104.

FIG. 2 is a schematic cross-sectional view of two bonded wafers 200 after the wafer thinning process in accordance with embodiments of the technology. For the wafer thinning process, the inactive back portion 108 of the target semiconductor wafer 104 is thinned, such as by using an etching process (e.g., a dry etch) to remove the semiconductive material. After the wafer thinning process is completed, the target semiconductor wafer 104 can have a resulting thickness 212 that represents an overall characterization/estimation of a vertical dimension of the thinned semiconductor wafer 104. The resulting thickness 212 for the overall structure can correspond to the targeted/intended thickness measured from the bonded surface of the carrier wafer 102 to the opposing side of the semiconductor wafer 104. The actual thickness of the semiconductor wafer 104 at the bonding void 114 can be less than the targeted thickness. Using the example illustrated in FIG. 2, the vertical dimensions of the exposed dielectric structures 110B-D can match the resulting thickness 212 while the vertical dimension of the dielectric structure 110A can be less than the resulting overall thickness 212.

Capacitances at each of the dielectric structures 110A-D can be measured and analyzed to determine the resulting thickness 212 of the target semiconductor wafer 104. The capacitances can be measured using a conductive bond chuck 225 and one or more probe pads 220A-D. The conductive bond chuck can directly contact the carrier wafer 102 on a surface opposite the bonded surface, and the one or more probe pads 220A-D can directly contact the exposed surfaces of the dielectric structures 110A-D. The conductive bond chuck 225 and the one or more probe pads 220A-D can function as capacitor terminals, and the carrier wafer 102 and the one or more dielectric structures 110A-D can function as the dielectric separating the capacitor terminals. In some embodiments, the resulting capacitive structure has an expected capacitance which is compared with actual capacitances measured across the carrier wafer 102 and the one or more dielectric structures 110A-D. Various factors, such as existence of bonding voids, characteristics of bonding voids, and number of bonding voids, can contribute to variations in capacitances. For example, existence of the bonding void 114 between the dielectric structure 110A and the carrier wafer 102 results in a greater capacitance compared to the capacitance across the dielectric structure 110B and the carrier wafer 102 where there is no bonding void.

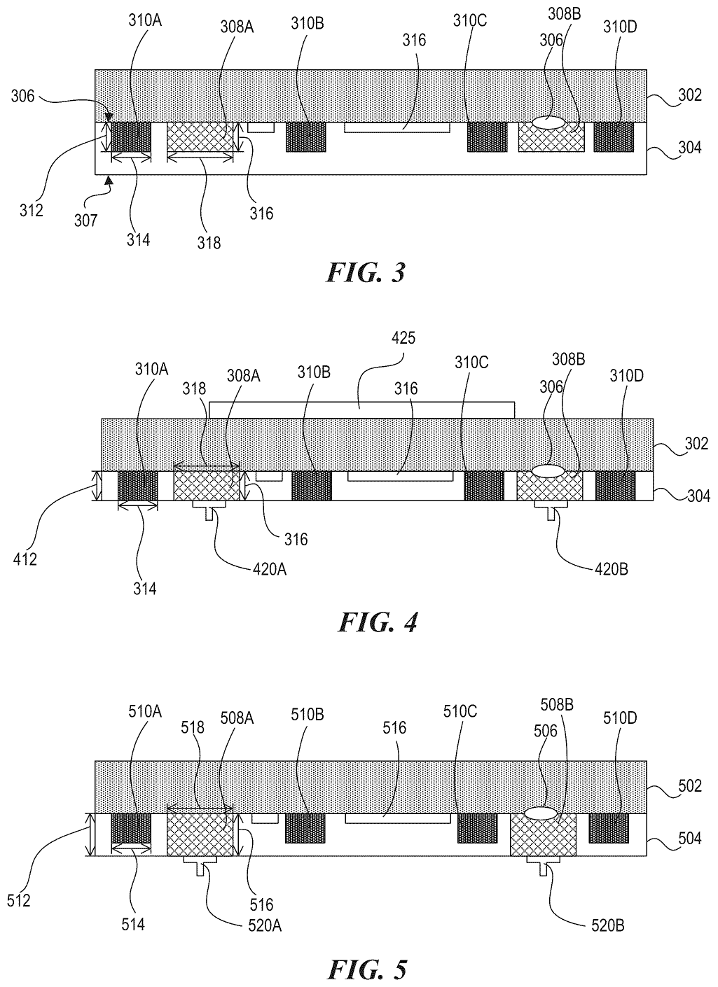

FIG. 3 is a schematic cross-sectional view of bonded wafers prior to the wafer thinning process in accordance with embodiments of the technology. Similar to the target semiconductor wafer 104 in FIG. 1, a target semiconductor wafer 304 can have an active front portion 306 and an inactive back portion 307. Active circuits 316 can be formed on the active front portion 306 of the target semiconductor wafer 304. Multiple cavities can be formed on the active front portion 306 of the target semiconductor wafer 304 then filled with dielectric material to build multiple dielectric structures 310A-D. The vertically extending dielectric structures 310A-D can provide an electrical function for the active circuits 316. For example, the dielectric structures 310A-D can include oxide material (e.g., SiO₂) and encase, surround, abut, or separate circuit components, such as doped regions. The dielectric structures 310A-D can include 2W structures/regions.

In addition to the vertically extending dielectric structures 310A-D, additional cavities can be formed on the active front portion 306 of the target semiconductor wafer 304 then filled with dielectric material to build multiple dielectric measurement structures 308A and 308B. The dielectric measurement structures 308A and 308B may be electrically isolated from the active circuits 316 and the dielectric structures 310A-D that provide an electrical function for the active circuits 316. In some embodiments, the dielectric measurement structures 308A and 308B are formed on scribe areas (e.g., areas of the wafer targeted for dicing or separating individual dies) of the target semiconductor wafer 304 to ensure that the dielectric measurement structures 308A and 308B are both electrically and physically separated from the active circuits 316. When the dielectric measurement structures 308A and 308B are formed on scribe areas, semiconductor dies resulting from the wafer can have the dielectric measurement structures 308A and 308B or portions thereof on or along their peripheral portions.

As shown in FIG. 3, the dielectric measurement structures 308A and 308B can have depths 316 equal to depths 312 of the dielectric structures 310A-D. The cavity depths and the corresponding depths of the dielectric measurement structures 308A and 308B and the dielectric structures 310A-D can correspond to a targeted thickness for the target semiconductor wafer 304.

The dielectric measurement structures 308A and 308B can have horizontal dimensions 318 different from horizontal dimensions 314 of the dielectric structures 310A-D. The purpose of different horizontal dimensions may be to distinguish the dielectric measurement structures 308A and 308B from the dielectric structures 310A-D and the active circuits 316. In some embodiments, the dielectric measurement structures are designed to have horizontal dimension 318 greater than horizontal dimensions of probe pads that are used in conjunction with a conductive bond chuck to measure capacitance across the dielectric measurement structures and the carrier wafer 302.

The target semiconductor wafer 304 can be bonded with the carrier wafer 302 for safe handling and processing prior to the wafer thinning process. Bonding voids 306 can be inadvertently formed between the carrier wafer 302 and the active front portion 306 of the target semiconductor 304. The resulting bonding voids 306 can vary in size, quantity, and location. For example, the bonding voids 306 can be formed adjacent to the active circuits 316, the dielectric structures 310A-D, the dielectric measurement structures 308A and 308B, and other locations where no electric structures exist.

FIG. 4 is a schematic cross-sectional view of bonded wafers after the wafer thinning process in accordance with embodiments of the technology. For the wafer thinning process, the inactive back portion of the target semiconductor wafer 304 can be thinned, such as by using an etching process (e.g., a dry etch) to remove the semiconductive material until the dielectric measurement structures 308A and 308B are exposed. After the wafer thinning process is completed, the target semiconductor wafer 304 can have a resulting thickness 412 that represents an overall characterization/estimation of a vertical dimension of the thinned semiconductor wafer 304. The resulting thickness 412 for the overall structure can correspond to the targeted/intended thickness measured from the bonded surface of the carrier wafer 302 to the opposing side of the semiconductor wafer 304. The actual thickness of the semiconductor wafer 304 at the bonding void 306 can be less than the targeted thickness. For example, as illustrated in FIG. 4, the vertical dimension 316 of the exposed dielectric measurement structure 308A which has no adjacent bonding voids can match the resulting thickness 412 while the vertical dimension of the exposed dielectric measurement structure 308B can be less than the resulting overall thickness 412. In some embodiments, the wafer thinning process can use the exposure/detection of the dielectric measurement structures 308 as an indication of reaching the targeted thickness.

Capacitances at each of the dielectric measurement structures 308A and 308B can be measured and analyzed to verify the resulting thickness 412 of the target semiconductor wafer 304. The capacitances can be measured using a conductive bond chuck 425 and one or more probe pads 420A and 420B. The conductive bond chuck can directly contact the carrier wafer 102 on a surface opposite the bonded surface, and the one or more probe pads 420A and 420B can directly contact the exposed surfaces of the dielectric measurement structures 308A and 308B. As explained with respect to FIG. 3, the horizontal dimensions 318 of the dielectric measurement structures 308A and 308B can be greater than the horizontal dimensions of the probe pads 420A and 420B to simplify capacitance measurement process and readily identify exposed surfaces of the dielectric measurement structures 308A and 308B. The conductive bond chuck 425 and the one or more probe pads 420A and 420B can function as capacitor terminals, and the carrier wafer 302 and the one or more dielectric measurement structures 308A and 308B can function as the dielectric separating the capacitor terminals. In some embodiments, the resulting capacitive structure has an expected capacitance which can be used to derive thresholds for evaluating actual capacitances measured across the carrier wafer 302 and the one or more dielectric measurement structures 308A and 308B. Various factors, such as existence of bonding voids, characteristics of bonding voids, and number of bonding voids, can contribute to variations in capacitances. For example, existence of the bonding void 306 between the dielectric measurement structure 308B and the carrier wafer 302 results in a greater capacitance compared to the expected capacitance across the dielectric measurement structure 308A and the carrier wafer 302 where there is no bonding void.

The dielectric measurement structures 308A and 308B can include material configured to facilitate the capacitance measurement. Some examples of the dielectric measurement structures 308A and 308B can include ZrO₂, HfO₂, SiON, and/or the like, such as for DRAM applications. Accordingly, the dielectric measurement structures 308A and 308B can correspond to structures different/separate from and/or in addition to the dielectric structures 310A-D (e.g., the 2W regions). In some embodiments, the dielectric measurement structures 308A and 308B can include oxide material different from the dielectric structures 310A-D.

The dielectric measurement structures 308A and 308B can be formed when the wafers are a finished product (e.g., a CMOS wafer). The dielectric measurement structures 308A and 308B can also be formed using a via-first or a via-middle process. In some embodiments, the dielectric measurement structures 308A and 308B can be formed using an Atomic Layer Deposition (ALD) process.

FIG. 5 is a schematic cross-sectional view of bonded wafers 502 and 504 after the wafer thinning process in accordance with embodiments of the technology. As illustrated in FIG. 5, the vertical dimensions 516 of the dielectric measurement structures 508A and 508B can be configured to be greater than the vertical dimensions of the dielectric structures 510A-D. The vertical dimensions 516 of the dielectric measurement structures 508A and 508B can be configured to be less than the initial thickness of a target semiconductor wafer 504 such that the resulting thickness 512 of the target semiconductor wafer 504 is equal to the vertical dimensions 516 after the wafer thinning process is completed and the dielectric measurement structures 508A and 508B are exposed.

Using the example illustrated in FIG. 5, the resulting thickness 512 of the target semiconductor wafer 504 can be greater than the targeted thickness of the target semiconductor wafer 504. In one example, variation of capacitances measured at each of the dielectric measurement structures 508A and 508B using probe pads 520A and 520B is analyzed. Upon determining that the variation of the measured capacitances is outside of a predetermined threshold range due to various factors such as existence of bonding voids, characteristics of bonding voids, and number of bonding voids, the bonded wafers are disposed. In some embodiments, if the difference between the resulting thickness of the thinned target semiconductor wafer 504 and the target thickness is greater than a threshold value such that reworking the target semiconductor wafer 504 is possible, the bonded wafers are separated to allow reworking of the target semiconductor wafer 504 and avoid disposing the bonded wafers. In other words, the dielectric measurement structures 508A and 508B can be used to check for bonding voids during the wafer thinning process and before potentially damaging the active circuitry 516 (e.g., due to excessive thinning caused by the voids). The dielectric measurement structures 508A and 508B can allow for the bonded structures to be adjusted, thereby eliminating the voids and avoiding damages to the active circuitry 516 during the subsequent/continuing wafer thinning process.

In another example, upon determining that the variation of the measured capacitances is within a predetermined threshold range, the target semiconductor wafer 504 is further thinned to the target thickness. During the wafer thinning process, the dielectric measurement structures 508A and 508B may be thinned such that resulting vertical dimensions are less than the initial vertical dimensions 516. The resulting vertical dimension of the exposed dielectric measurement structures 508A can match the new resulting thickness while the resulting vertical dimension of the exposed dielectric measurement structure 508B can be less than the resulting overall thickness, due to the existence of the bonding void 506.

The dielectric measurement structures 508A and 508B can be similar to the dielectric measurement structures 308A and 308B of FIG. 3 and FIG. 4. For example, the dielectric measurement structures 508A and 508B can include similar material and/or be formed using similar manufacturing processes.

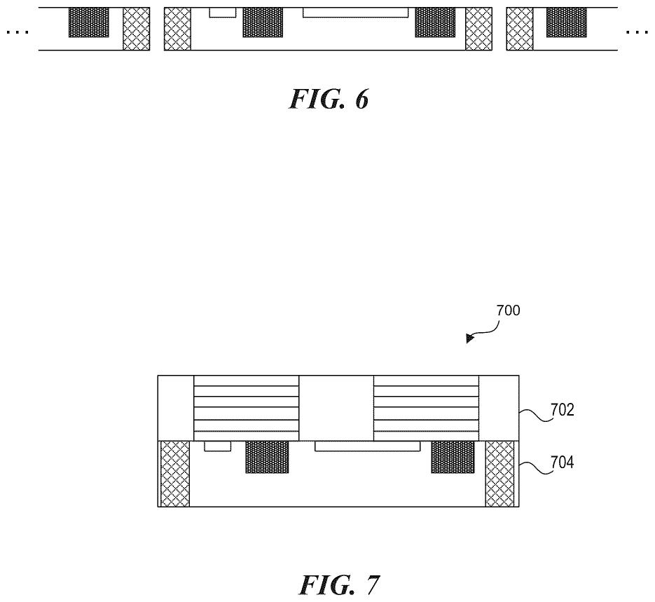

FIG. 6 is a schematic cross-sectional view of a resulting semiconductor die after singulation in accordance with embodiments of the technology. After determining that a target semiconductor wafer has achieved a desired target thickness through the wafer thinning process as described in FIGS. 1-5, the target semiconductor wafer can be isolated from the carrier wafer. To enhance the structural integrity of the resulting ultra-thin target semiconductor wafer, various debonding processes can be used. For example, if the carrier wafer is made of glass, an excimer laser light can be introduced to the glass carrier wafer, which is transparent at the laser wavelength, resulting in gentle debonding of the target semiconductor wafer from the carrier wafer.

The thinned wafer can be diced, thereby singulating the individual semiconductor dies. For example, the scribe regions can be cut to separate the individual dies from the target semiconductor wafer. In some embodiments, the singulated die can include a memory device, such as a memory array die, an array control die (e.g., a CMOS die), or the like.

In some embodiments, the thinned and singulated device can correspond to a final device targeted by a manufacturing process. In other embodiments, the thinned and singulated device can be used to manufacture a different device or a combination device. FIG. 7 is a schematic view of wafer bonded dies (e.g., a combined or a bonded device 700) in accordance with embodiments of the technology. FIG. 7 can correspond to a singulated semiconductor die of FIG. 6 bonded to another semiconductor die. Using the example illustrated in FIG. 7, first device 702 can be a memory array that includes memory cells. Second device 704 can be a control circuit (e.g., resulting from a CMOS wafer) for the memory array of the first device 702. One or more of the devices 702 and 704 can be an ultra-thinned wafer resulting from the wafer thinning process as described in FIGS. 1-6. For example, a set of wafers including one or more thinned wafers may be bonded to each other and then singulated. Otherwise, the wafers can be singulated first, and the resulting semiconductor devices can be bonded or mounted to each other.

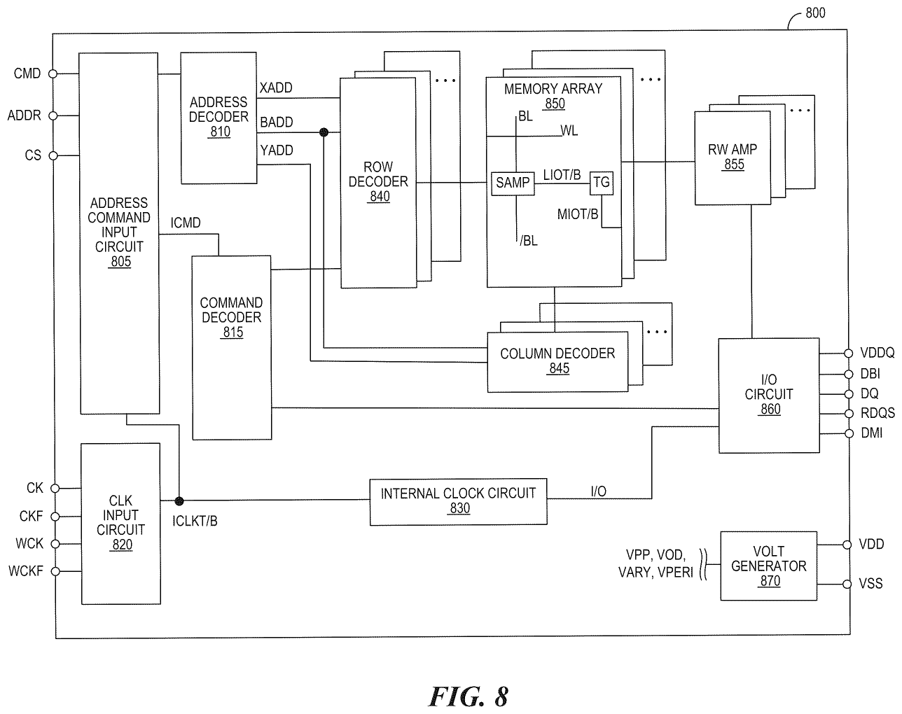

The resulting thinned device can be used for various applications. As an example, FIG. 8 is a block diagram of an apparatus 800 (e.g., a semiconductor die assembly, including a three-dimensional integration (3DI) device or a die-stacked package) in accordance with an embodiment of the technology. The apparatus 800 can include a DRAM or a portion thereof that includes one or more dies/chips. Also, the apparatus 800 can include the target semiconductor wafer 104 of FIG. 2, the target semiconductor wafer 304 of FIG. 4, the target semiconductor wafer 504 of FIG. 5, the singulated die of FIG. 6, the first device 702 of FIG. 7, the second die 704 of FIG. 7, the combined device 700 of FIG. 7, or a combination thereof.

The apparatus 800 may include an array of memory cells, such as memory array 850. The memory array 850 may include a plurality of banks (e.g., banks 0-15), and each bank may include a plurality of WLs, a plurality of DLs, and a plurality of memory cells arranged at intersections of the word-lines and the bit lines. Memory cells can include any one of a number of different memory media types, including capacitive, magnetoresistive, ferroelectric, phase change, or the like. Details regarding the structure of the WLs, the DLs, and the memory cells are described below.

The selection of a word-line WL may be performed by a row decoder 840, and the selection of a digit-line DL may be performed by a column decoder 845. Sense amplifiers (SAMP) may be provided for coupled digit-line DL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 815, the row decoders 840, the column decoders 845, any control circuitry of the memory array 850, or any combination thereof. The memory array 850 may also include plate lines and related circuitry for managing their operation.

The apparatus 800 may employ a plurality of external terminals that include command and address terminals coupled to a command bus and an address bus to receive command signals (CMD) and address signals (ADDR), respectively. The apparatus 800 may further include a chip select terminal to receive a chip select signal (CS), clock terminals to receive clock signals CK and CKF, data clock terminals to receive data clock signals WCK and WCKF, data terminals DQ, RDQS, DBI, DMI, power supply terminals VDD, VSS, and VDDQ.

The command terminals and address terminals may be supplied with an address signal and a bank address signal (not shown in FIG. 8) from outside. The address signal and the bank address signal supplied to the address terminals can be transferred, via a command/address (CA) input circuit 805, to an address decoder 810. The address decoder 810 can receive the address signals and supply a decoded row address signal (XADD) to the row decoder 840, and a decoded column address signal (YADD) to the column decoder 845. The address decoder 810 can also receive the bank address signal and supply the bank address signal to both the row decoder 840 and the column decoder 845.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 800 to respond to commands and addresses provided to the command and address terminals. When an active chip select signal is provided to the apparatus 800, the commands and addresses can be decoded, and memory operations can be performed. The command signals may be provided as internal command signals ICMD to a command decoder 815 via the command/address input circuit 805. The command decoder 815 may include circuits to decode the internal command signals ICMD to generate various internal signals and commands for performing memory operations, for example, a row command signal to select a word-line and a column command signal to select a bit line. The command decoder 815 may further include one or more registers for tracking various counts or values (e.g., counts of refresh commands received by the apparatus 800 or self-refresh operations performed by the apparatus 800).

Read data can be read from memory cells in the memory array 850 designated by row address (e.g., address provided with an active command) and column address (e.g., address provided with the read). The read command may be received by the command decoder 815, which can provide internal commands to input/output circuit 860 so that read data can be output from the data terminals DQ, RDQS, DBI, and DMI via read/write amplifiers 855 and the input/output circuit 860 according to the RDQS clock signals. The read data may be provided at a time defined by read latency information RL that can be programmed in the apparatus 800, for example, in a mode register (not shown in FIG. 8). The read latency information RL can be defined in terms of clock cycles of the CK clock signal. For example, the read latency information RL can be a number of clock cycles of the CK signal after the read command is received by the apparatus 800 when the associated read data is provided.

Write data can be supplied to the data terminals DQ, DBI, and DMI according to the WCK and WCKF clock signals. The write command may be received by the command decoder 815, which can provide internal commands to the input/output circuit 860 so that the write data can be received by data receivers in the input/output circuit 860 and supplied via the input/output circuit 860 and the read/write amplifiers 855 to the memory array 850. The write data may be written in the memory cell designated by the row address and the column address. The write data may be provided to the data terminals at a time that is defined by write latency WL information. The write latency WL information can be programmed in the apparatus 800, for example, in the mode register. The write latency WL information can be defined in terms of clock cycles of the CK clock signal. For example, the write latency information WL can be a number of clock cycles of the CK signal after the write command is received by the apparatus 800 when the associated write data is received.

The power supply terminals may be supplied with power supply potentials VDD and Vss. These power supply potentials VDD and Vss can be supplied to an internal voltage generator circuit 870. The internal voltage generator circuit 870 can generate various internal potentials VPP, VOD, VARY, VPERI, and the like based on the power supply potentials VpD and Vss. The internal potential Vpp can be used in the row decoder 840, the internal potentials Von and VARY can be used in the sense amplifiers included in the memory array 850, and the internal potential VPERI can be used in many other circuit blocks.

The power supply terminal may also be supplied with power supply potential VDDQ. The power supply potential VDDQ can be supplied to the input/output circuit 860 together with the power supply potential VSS. The power supply potential VDDQ can be the same potential as the power supply potential Vss in an embodiment of the present technology. The power supply potential VDDQ can be a different potential from the power supply potential Vpp in another embodiment of the present technology. However, the dedicated power supply potential VDDQ can be used for the input/output circuit 860 so that power supply noise generated by the input/output circuit 860 does not propagate to the other circuit blocks.

The clock terminals and data clock terminals may be supplied with external clock signals and complementary external clock signals. The external clock signals CK, CKF, WCK, WCKF can be supplied to a clock input circuit 820. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 820 can receive the external clock signals. For example, when enabled by a clock/enable signal from the command decoder 815, an input buffer can receive the clock/enable signals. The clock input circuit 820 can receive the external clock signals to generate internal clock signals ICLK. The internal clock signals ICLK can be supplied to an internal clock circuit 830. The internal clock circuit 830 can provide various phase and frequency controlled internal clock signals based on the received internal clock signals ICLK and a clock enable (not shown in FIG. 8) from the command/address input circuit 805. For example, the internal clock circuit 830 can include a clock path (not shown in FIG. 8) that receives the internal clock signal ICLK and provides various clock signals to the command decoder 815. The internal clock circuit 830 can further provide input/output (IO) clock signals. The IO clock signals can be supplied to the input/output circuit 860 and can be used as timing signals for determining output timing of read data and/or input timing of write data. The IO clock signals can be provided at multiple clock frequencies so that data can be output from and input to the apparatus 800 at different data rates. A higher clock frequency may be desirable when high memory speed is desired. A lower clock frequency may be desirable when lower power consumption is desired. The internal clock signals ICLK can also be supplied to the internal clock circuit 830 and thus various internal clock signals can be generated.

The apparatus 800 can be connected to any one of a number of electronic devices capable of utilizing memory for the temporary or persistent storage of information, or a component thereof. For example, a host device of apparatus 800 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 800; although in other embodiments, the host device may be indirectly connected to memory device (e.g., over a networked connection or through intermediary devices).

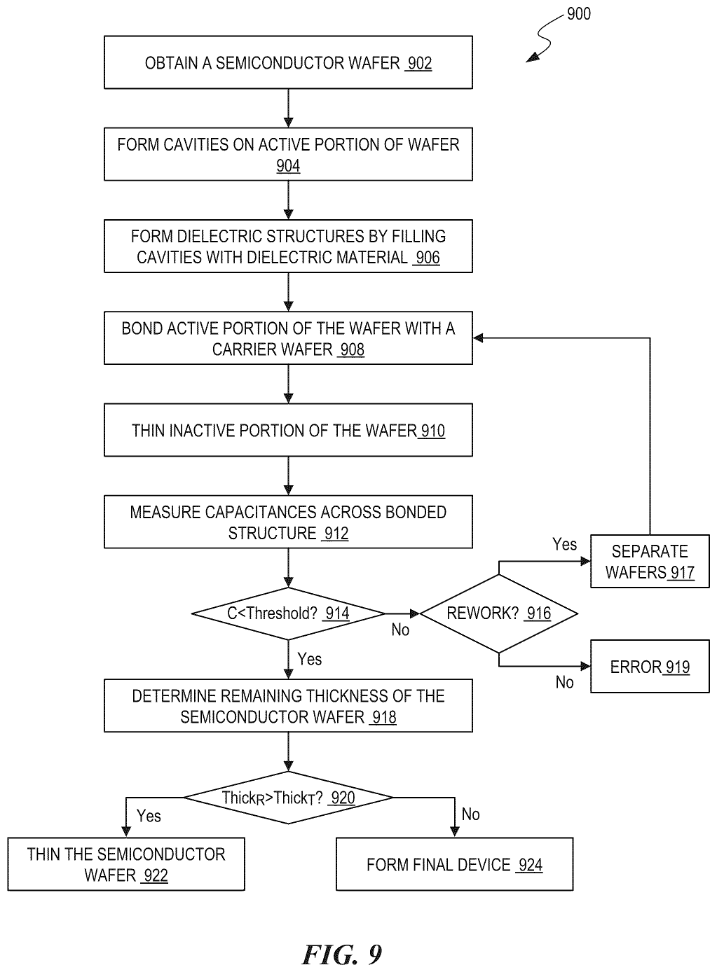

FIG. 9 is a flow diagram illustrating an example method 900 of manufacturing an apparatus (e.g., the target semiconductor wafer 104 of FIG. 2, the target semiconductor wafer 304 of FIG. 4, the target semiconductor wafer 504 of FIG. 5, the singulated die of FIG. 6, the first device 702 of FIG. 7 and/or the second die 704 of FIG. 7, the apparatus 800, or a combination thereof) in accordance with an embodiment of the technology. The method 900 can be related to (e.g., representing one or more portions or combinations of) the stages illustrated in FIG. 1-FIG. 8.

The method 900 can include obtaining a semiconductor wafer, such as illustrated at block 902. The obtained wafer can include active circuits. For example, the device manufacturer can obtain or manufacture semiconductor devices having active circuits thereon, such as the target semiconductor wafer 104 of FIG. 1, the target semiconductor wafer 304 of FIG. 3, or the like.

At block 904, the method 900 can include forming cavities on the active portion of the obtained wafer. For example, the manufacturer can form the cavities based on masking the active surface having openings at targeted locations, and then etching or removing the exposed or uncovered portion of the wafer through the openings. The cavities can be formed to have a target depth that matches the targeted thickness of the wafer. In other embodiments, the manufacturer can form the cavities with the target depth with a depth greater than the targeted thickness of the wafer, such as for assessing or detecting potential voids and triggering rework to improve the bonding. Details regarding the detection and rework are described below.

At block 906, the method 900 can include forming dielectric structures by filling the cavities with dielectric material. For example, the manufacturer can form the dielectric structures 110 of FIG. 1, the dielectric structures 310 of FIG. 3, and/or the dielectric measurement structures 308 of FIG. 3. In some embodiments, the dielectric structures 110, the dielectric structures 310, and/or the dielectric measurement structures 308 can include SiO₂. In other embodiments, the dielectric measurement structures 308 can include ZrO₂, HfO₂, SION, and/or the like. Also, the dielectric measurement structures 308 can be formed using the ALD process.

After completing the active circuit and the dielectric structures, the method 900 can include bonding the wafer (e.g., the active portion thereof) to a carrier wafer for further processing. For example, the active portion of the processed wafer can be bonded to the carrier wafer 102 of FIG. 1, 302 of FIG. 3, 502 of FIG. 5, etc. for a thinning process. The carrier wafer can increase and preserve the structural integrity of the processed wafer during transfer, thinning, and/or other similar physical manipulations.

At block 910, the method 900 can include thinning the inactive portions of the processed or targeted wafer. For example, the manufacturer can remove the inactive backside of the target semiconductor wafer 104, the target semiconductor wafer 304, or the like, such as through a chemical etching process, a dry etching process, a mechanical etching or grinding process, or the like. In some embodiments, the wafer can be thinned to a targeted final or intermediate thickness. Additionally or alternatively, the wafer can be thinned until the dielectric structures become exposed. In other words, the thinning process can use the exposer of the dielectric structures as a trigger or a verification to stop or pause the thinning process.

At block 912, the method 900 can include measuring the capacitances across the bonded structure. In some embodiments, the method 900 can include applying the probe pads 220 of FIG. 2, 420 of FIG. 4, 520 of FIG. 5, or the like on one or more of the exposed dielectric structures. The method 900 can also include using the conductive bond chuck 225 of FIG. 2, 425 of FIG. 4, or the like applied to the opposite side/surface of the exposed dielectric structures. For example, the method 900 can include using the conductive bond chuck and the probe pads as opposing terminals of a capacitor with the dielectric structure disposed in between. Accordingly, the opposing terminals can be used to measure the capacitance between the conductive bond chuck and the probe pads. For example, the manufacturer can apply a voltage to one of the terminals and measure a response (e.g., a voltage or a timing/rate for the voltage change).

At decision block 914, the method 900 can include comparing the measured capacitance to a predetermined threshold. In some embodiments, the predetermined threshold can represent an acceptable level or amount of voids. In other words, the predetermined threshold can represent the capacitance expected for the dielectric structure and the carrier wafer (e.g., without any voids between the bonded wafers). Accordingly, the method 900 can determine whether the measured capacitance matches or is within a threshold range of the expected capacitance level.

In some embodiments, when the measured capacitance is outside of (e.g., lower than) the threshold capacitance level, the method 900 can include determining whether to rework the bonded structure. At decision block 916, the method 900 can include comparing the thickness of the processed wafer to the intermediate thickness. When the thickness is less than the intermediate thickness (at, e.g., the targeted final thickness), the method can determine a processing error and forego the rework process as illustrated at block 919.

When the thickness is at or greater than the intermediate thickness, the unsatisfactory capacitance level can trigger a rework process. For example, the method 900 can include separating the wafers as illustrated at block 917. Subsequently, the method 900 can include rebonding the wafers as illustrated by a feedback loop to block 908. The rebonding process can remove or result in decrease or removal of one or more voids between the bonded wafers.

When the measured capacitance is satisfactory in comparison to the threshold, the method 900 can calculate a remaining thickness of the targeted/processed semiconductor wafer as illustrated at block 918. At decision block 918, the method 900 can include comparing the remaining thickness (ThickR) to the final targeted thickness (ThickT) for the wafer. When the remaining structure is thicker than the target, the method 900 can include further thinning the wafer to meet the final targeted thickness for the wafer. In some embodiments, the dielectric structure can have a depth that is greater than the targeted thickness of the wafer. Accordingly, the method 900 can include pausing the thinning process at an intermediate depth that matches the depth of the dielectric structure. This way, if the bonded structure includes voids, the method 900 can detect a rework condition and re-bond the structures (e.g., blocks 916, 917, 908, and so forth) before thinning the targeted wafer to the target depth. By detecting voids before reaching the target thickness, the method 900 can avoid damaging the active circuits and thus the wafer. At block 922, the method 900 can confirm the absence or the acceptable levels of the void and continue the thinning process until the wafer reaches the target thickness.

At block 924, the method 900 can include forming the final device using the thinned wafer. For example, the method 900 can include bonding the thinned wafer to another wafer, singulating the wafer(s), and/or bonding the singulated die(s) to each other or another structure. Accordingly, the method 900 can be used to manufacture the combined device 700 of FIG. 7, the apparatus 800 of FIG. 800 or a combination thereof using the wafer thinned and tested as described above.

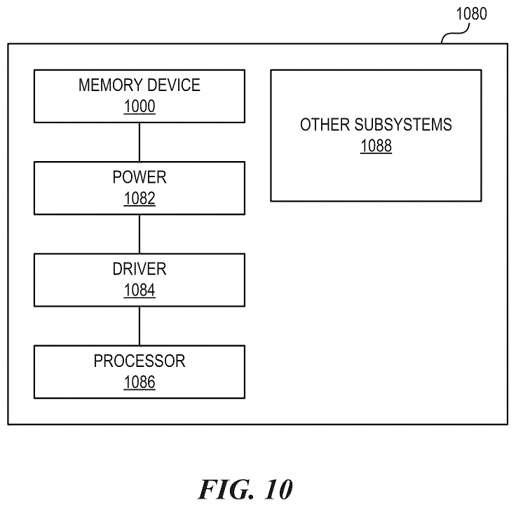

FIG. 10 is a schematic view of a system that includes an apparatus in accordance with an embodiment of the present technology. Any one of the foregoing apparatuses (e.g., memory devices) described above with reference to FIGS. 1-9 can be incorporated into any of a myriad of larger and/or more complex systems, a representative example of which is system 1080 shown schematically in FIG. 10. The system 1080 can include a memory device 1000, a power source 1082, a driver 1084, a processor 1086, and/or other subsystems or components 1088. The memory device 1000 can include features generally similar to those of the apparatus described above with reference to one or more of the FIGS., and can therefore include various features for performing a direct read request from a host device. The resulting system 1080 can perform any of a wide variety of functions, such as memory storage, data processing, and/or other suitable functions. Accordingly, representative systems 1080 can include, without limitation, hand-held devices (e.g., mobile phones, tablets, digital readers, and digital audio players), computers, vehicles, appliances and other products. Components of the system 1080 may be housed in a single unit or distributed over multiple, interconnected units (e.g., through a communications network). The components of the system 1080 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of dynamic random access memory (DRAM) devices. Apparatuses configured in accordance with other embodiments of the present technology, however, can include other types of suitable storage media in addition to or in lieu of DRAM devices, such as, devices incorporating NOR-based non-volatile storage media, NAND-based flash device, magnetic storage media, phase-change storage media, ferroelectric storage media, etc.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

What is claimed is:

1. A method of manufacturing a semiconductor device, the method comprising:
obtaining a carrier wafer;
obtaining a semiconductor wafer to perform thinning,
wherein the semiconductor wafer includes one or more thickness control structures with a targeted thickness such that the one or more thickness control structures are exposed when the semiconductor is thinned to the targeted thickness; and
wherein the semiconductor wafer includes one or more dielectric structures with a thickness greater than or equal to the targeted thickness;
bonding the carrier wafer with an active side of the semiconductor wafer;
thinning the semiconductor wafer until the one or more dielectric structures are exposed;
measuring capacitances across the one or more dielectric structures,
wherein the measured capacitances represent measures corresponding to existence and/or amount of bonding voids between the carrier wafer and the semiconductor wafer and a remaining thickness of the semiconductor wafer.

2. The method of claim 1, wherein obtaining the semiconductor wafer includes:
forming one or more measurement vias on an active surface of the semiconductor wafer, wherein the one or more measurement vias have a depth matching the thickness; and
filling the one or more measurement vias with the one or more dielectric structures.

3. The method of claim 1, wherein the targeted thickness is measured from an active surface of the semiconductor wafer toward an inactive surface thereof.

4. The method of claim 1, wherein the one or more thickness control structures are dielectric so as to allow measurement of capacitance across the one or more thickness control structures.

5. The method of claim 1, wherein the remaining thickness of the semiconductor wafer is greater than the targeted thickness of the semiconductor wafer, further comprising:
analyzing the measured capacitances across the one or more dielectric structures to determine that the amount of bonding voids between the carrier wafer and the semiconductor wafer is outside of a predetermined threshold range; and
in response to the determination, reworking the semiconductor wafer.

6. The method of claim 1, wherein the remaining thickness of the semiconductor wafer is greater than the targeted thickness of the semiconductor wafer, further comprising:
analyzing the measured capacitances across the one or more dielectric structures to determine that the amount of bonding voids between the carrier wafer and the semiconductor wafer is within a predetermined threshold range; and
in response to the determination, further thinning the semiconductor wafer to the targeted thickness of the semiconductor wafer.

7. The method of claim 1, wherein measuring the capacitances across the one or more dielectric structures includes:
placing the bonded wafers on a bonding chuck such that the carrier wafer touches the bonding chuck; and
placing probe pads on the one or more exposed dielectric structures,
wherein the bonding chuck and the probe pads represent opposing conductive plates that provide the capacitances across the one or more dielectric structures.

8. The method of claim 1, further comprising:
stopping thinning and disposing the semiconductor wafer where a variation of the capacitances exceeds a predetermined threshold value.

9. The method of claim 1, further comprising:
bonding the thinned semiconductor wafer to a second wafer.

10. The method of claim 9, wherein bonding the thinned semiconductor wafer to the second wafer includes bonding memory array circuits to array control circuits.

11. The method of claim 1, wherein:
the semiconductor wafer includes scribe zones between groupings of circuits;
the dielectric structures are located in the scribe zones; and
further comprising:
dicing the thinned semiconductor wafer at the scribe zones to singulate semiconductor dies that each have a grouping of the circuits.

12. A semiconductor apparatus, comprising:
a semiconductor substrate having a thickness defined by an active side and an opposing inactive side, the semiconductor substrate having a cavity extending from the active side to the inactive side;
circuits on the active side; and
a dielectric fill separated from the circuits along a lateral direction and occupying the cavity in the semiconductor substrate,
wherein the dielectric fill is electrically and physically separate from the circuits, and
wherein the dielectric fill is exposed on the active side and the inactive side for forming a capacitor structure with a carrier wafer and a probe pad to provide a capacitance measure representative of one or more bonding voids between the carrier wafer and the semiconductor substrate during manufacturing.

13. The semiconductor apparatus of claim 12, wherein the semiconductor substrate has a thickness of 5 μm or less.

14. The semiconductor apparatus of claim 12, wherein the dielectric fill is located on a peripheral edge of the semiconductor substrate, wherein the peripheral edge corresponds to a scribe area of a wafer used to form the semiconductor substrate.

15. The semiconductor apparatus of claim 12, wherein the dielectric fill provides no electrical affect to the circuits.

16. The semiconductor apparatus of claim 12, wherein the semiconductor apparatus comprises a memory device.

17. A semiconductor memory device, comprising:
a first semiconductor device; and
a second semiconductor device bonded to and over the first semiconductor device,
wherein at least one of the first and second semiconductor devices includes a dielectric fill extending between and exposed at a top surface and a bottom surface thereof,
wherein the dielectric fill is configured to form a capacitor structure with a carrier wafer and a probe pad to provide a capacitance measurement during manufacturing of the at least one of the first and second semiconductor devices, the capacitance measurement representative of one or more bonding voids between the carrier wafer and the semiconductor substrate,
wherein the first and second semiconductor devices include a memory array and a control circuit for the memory array bonded to the memory array.

18. The semiconductor memory device of claim 17, wherein the dielectric fill is located on a peripheral edge portion of the at least one of the first and second semiconductor devices.

19. The semiconductor memory device of claim 17, wherein the dielectric fill is electrically isolated or disconnected from the memory array and the control circuit.
